(19) United States
(12) Patent Application Publication
(10) Pub. No.: US 2015/0102713 A1
(43) Pub. Date: Apr. 16, 2015

(54) CASING FOR RECEIVING HARD DISK DRIVE

(71) Applicant: HON HAI PRECISION INDUSTRY CO., LTD., New Taipei (TW)

(72) Inventors: Chih-Hao LIN, New Taipei (TW); Yi-Hsien LEE, New Taipei (TW)

(73) Assignee: HON HAI PRECISION INDUSTRY CO., LTD., New Taipei (TW)

(21) Appl. No.: 14/067,964

(22) Filed: Oct. 31, 2013

(30) Foreign Application Priority Data
Oct. 16, 2013 (TW) 102137401

(51) Int. Cl. G11B 33/14; H05K 5/00; G11B 33/02

(52) U.S. Cl. CPC G11B 33/1493; G11B 33/022; H05K 5/0004
USPC 312/223.2

(57) ABSTRACT

A casing for receiving a hard disk drive includes a top wall, a bottom wall, two sidewalls, and an end wall. A number of metal bars protrude from an inner surface of the top wall.

### BACKGROUND

1. Technical Field

The present disclosure relates to a casing for receiving a hard disk drive (HDD).

2. Description of Related Art

HDDs mounted in servers are easily affected by electromagnetic interference (EMI). However, conventional casings for HDDs do not help much in reducing EMI on the HDDs. Therefore, there is room for improvement in the art.

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawings, all the views are schematic, and like reference numerals designate corresponding parts throughout the several views.

FIG. 1 is an exploded, isometric view of an embodiment of a casing for a hard disk drive, wherein the casing forms a plurality of metal bars.

FIG. 2 is a curve diagram showing electromagnetic interference (EMI) on the hard disk drive using the casing of FIG. 1.

FIG. 3 is a curve diagram showing EMI on the hard disk drive using a conventional casing without the metal bars.

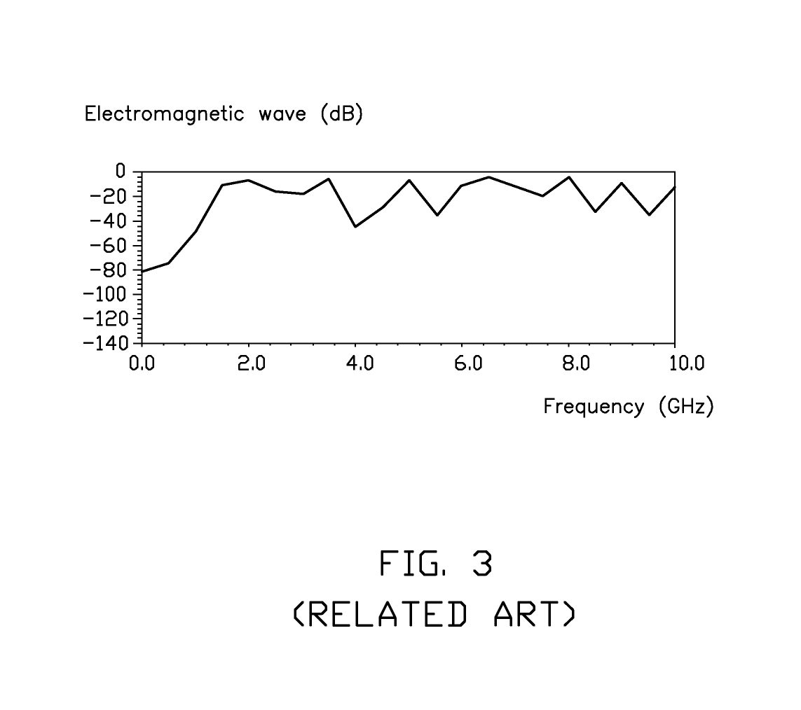

### DETAILED DESCRIPTION

The disclosure, including the accompanying drawings, is illustrated by way of example and not by way of limitation. It should be noted that references to “an” or “one” embodiment in this disclosure are not necessarily to the same embodiment, and such references mean “at least one.”

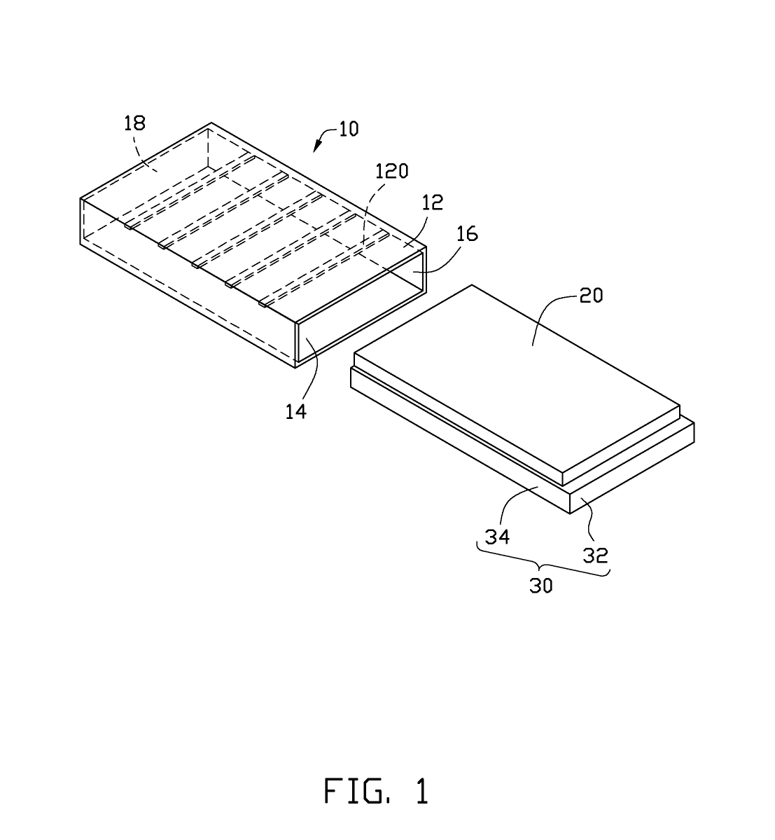

Referring to FIG. 1, an embodiment of a casing 10 is provided for receiving a hard disk drive (HDD) 20 mounted in a frame 30. The frame 30 includes a handle 32 and two arms 34 extending from opposite ends of the handle 32. The HDD 20 is mountably received in a space cooperatively defined by the handle 32 and the arms 34.

The casing 10 is made of metal material and includes a top wall 12, a bottom wall 14, two sidewalls 16 connected between the top and bottom walls 12 and 14, and an end wall 18 connected between the sidewalls 16 and the top and bottom walls 12 and 14.

A plurality of metal bars 120 protrudes from an inner surface of the top wall 12. The metal bars 120 are connected substantially perpendicularly between the sidewalls 16 to reduce electromagnetic interference (EMI) on the HDD 20.

The HDD 20 is received in the casing 10. A distance, such as 1.8 millimeters (mm), is kept between the HDD 20 and the metal bars 120 for conveniently installing the HDD 20.

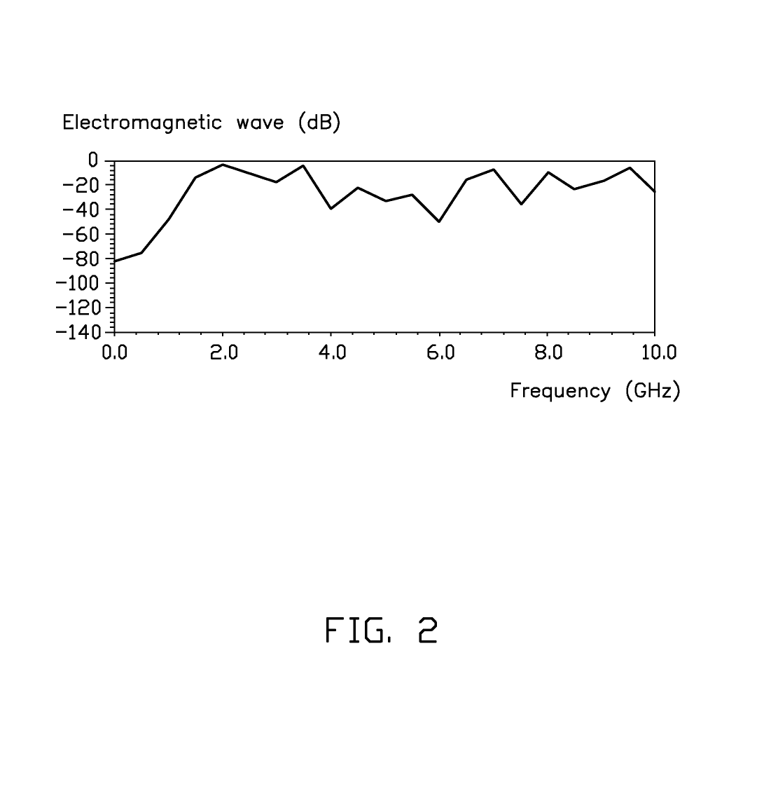

In this embodiment, the HDD has a height of about 25 mm. A thickness of each of the top wall 12, the bottom wall 14, the sidewalls 16, and the end wall 18 is about 1.2 mm. The casing 10 is about 30.4 mm in height, about 186 mm in length, and about 107.4 mm in width. A thickness of each metal bar 120 and a width of each metal bar 120 are both about 1.2 mm. As shown in FIG. 2, when the casing 10 forms the metal bars 120, when a transmission frequency of the HDD 20 is 6 gigahertz (GHz), an intensity of the electromagnetic waves is reduced about 35 decibels (dB). The intensity of the electromagnetic waves can be reduced more if the metal bars 120 are greater in height.

In other embodiments, the metal bars 120 can protrude from the bottom wall 14 or the sidewalls 16.

It is believed that the present embodiments and their advantages will be understood from the foregoing description, and various changes may be made thereto without departing from the spirit and scope of the description or sacrificing all of their material advantages, the examples hereinbefore described merely being exemplary embodiments.

What is claimed is:

1. A casing for receiving a hard disk drive (HDD), the casing comprising:
a top wall, wherein a plurality of metal bars protrudes from an inner surface of the top wall; and
a bottom wall;
two sidewalls connected between opposite sides of the top and bottom walls; and
an end wall connected between ends of the top and bottom walls.

2. The casing of claim 1, wherein the plurality of metal bars is connected between the sidewalls.

3. The casing of claim 1, wherein the casing is about 30.4 millimeters (mm) in height to receive the HDD with about 25 mm in height, a thickness of each of the top and bottom walls is about 1.2 mm, a height of each metal bar in a direction perpendicular to the top wall is about 1.2 mm.

4. The casing of claim 1, wherein a thickness of each of the sidewalls and end walls is about 1.2 mm, a width of each metal bar in an extension direction of the top wall is about 1.2 mm.

5. The casing of claim 1, wherein a distance is kept between the plurality of metal bars and the HDD.

6. The casing of claim 5, wherein the distance is about 1.8 mm.
